(19) United States
(12) Patent Application Publication
(10) Pub. No.: US 2003/0122255 A1
(43) Pub. Date: Jul. 3, 2003

(54) Ball grid array package

(76) Inventor: Jen-Kuang Fang, Kaoshiung (TW)

Correspondence Address: SEYFARTH SHAW, 55 EAST MONROE STREET, SUITE 4200, CHICAGO, IL, 60603-5803, US

(21) Appl. No.: 10/282,768

(22) Filed: Oct. 29, 2002

(30) Foreign Application Priority Data
Dec. 27, 2001 (TW) 090132528

(51) Int. Cl. H01L 23/48

(52) U.S. Cl. 257/738

(57) ABSTRACT

The present invention discloses a ball grid array package. The ball grid array package of the present invention comprises a substrate and at least one chip, and the substrate has a plurality of ball pads. The present invention disposes a plurality of testing pads having openings on the substrate, and the ball pads are electrically connected to the testing pads. By the structure, a probe of a testing socket can contact with the testing pads, and keep the shape of the ball pads complete.

### BACKGROUND OF THE INVENTION

1. Field of the Invention

The present invention relates to a ball grid array package (BGA), more specifically, to a ball grid array package for solving the electricity problem caused by solder ball welding defects.

2. Background of the Invention

For the past ten years, the popularity of the ball grid array (BGA) package has been incredibly growing. The overall BGA market, in the marketing forecast, will be growing three times other conventional packaging techniques. For the ball grid array package technique, the defect rate for each ball is required to be lower than tens in a million, and depends on how many solder balls each package has. It has become a very important issue as to how to adequately solve the ball-shape recess of solder balls caused by testing so as to induce the bad welding problems. For example, there will be hundreds of solder balls for each device, and if one ball has some problems, it will influence the electrical characteristics of the whole device. Even though the device could pass the testing conditions before delivery, its lifespan under normal use cannot be ensured.

FIG. 1 illustrates a cross-sectional view for the conventional ball grid array package. The ball grid array package 10 is to adhere the chip 11 onto the upper surface of the substrate 20, and using the wire-bonding technique to achieve the electrical connection between the chip and the substrate 20 by golden wires 12. The golden wires 12 and the chip 11 must be fully covered and protected by an encapsulant 13. A solder ball 31 is required to be formed at the ball pad 21 on the lower surface of the substrate 20 (as shown in FIG. 2), and it can then be connected to an external system (such as a motherboard) to serve as the path of signal transmission.

FIG. 2 illustrates a cross-sectional view for the substrate of the conventional ball grid array package and the testing socket. The ball grid array package 10 is placed in the testing socket 40, and a plurality of probes 41 in the socket 40 are used to contact with their corresponding solder balls 31. The testing socket 40 further uses the circuit to transmit testing signals and testing results with a testing machine. Because the encapsulant 13 is fixed on the surface of the substrate 20, the ball grid array package 30 will have the warpage effect, and each of the solder balls 31 will have a different height after reflowing, so that the encapsulant 13 must be applied with a certain pressure during testing to make each probe 41 fully contact with the corresponding solder ball 31 and to complete all the testing operations. Owing to the hardness of the metal material of the probe 41 being larger than that of the solder ball 31, a surface recession 32 will be generated on the solder ball 31. The solder ball 31 with the surface recession 32 will induce the welding void 33 during the following reflow process, and further result in the electrical connection failure or inferior signal transmission.

FIG. 3 shows a conventional ball grid array package 10, which is welded on the motherboard 50. Due to the solder ball with surface recession during the testing process, the ball grid array package 10 will exhibit a phenomenon of welding voids 33 after welding solder balls between the ball grid array package 10 and the motherboard. Even though the final products can pass the testing, they might be fail soon during subsequent use due to bad reliability.

### SUMMARY OF THE INVENTION

The main object of the present invention is to provide a reliable testing model for the ball grid array package, which not only can normally use the testing socket to perform the final test (FT), but also can solve the inferior welding problems to increase the product yield and further enhance the product reliability and extend the lifespan of final products.

To this end, the present invention discloses a ball grid array package and method of testing the same, which can be practically applied to the packaging process of electrical devices. The method includes the following steps:

First, for the substrate design of the ball grid array package, it is required to design another testing pad beside the ball pad. The area of the testing pad is sufficient for contacting with the probe of the testing socket, and using circuits for connecting these two pads. The present invention uses such circuit design to finish the entire processes for the package, and the solder balls are welded on the original ball pad in the same manner.

Next, the device after the packaging is put into a testing socket, and made contacted with the probes in the testing socket with the preserved testing pad on the substrate, and to complete the functional certification for the device in a fixed testing time period. Since none of the solder balls are contacted with the probes in the testing process, the shapes of the solder balls are still kept with their completeness. Thus, the present invention can completely solve the above-mentioned problems of the conventional techniques without further increasing additional testing steps.

### BRIEF DESCRIPTION OF THE DRAWINGS

The invention will be described according to the appended drawings, in which:

FIG. 1 shows a cross-sectional diagram of a prior ball grid array package;

FIG. 2 shows a cross-sectional diagram of the substrate and testing socket of a prior ball grid array package;

FIG. 3 shows a schematic diagram of the defect phenomenon of a prior ball grid array package;

FIG. 4 shows a schematic diagram of circuit routing on a ball grid array package according to the invention; and

FIG. 5 shows a cross-sectional diagram of one embodiment of the ball grid array package according to the invention.

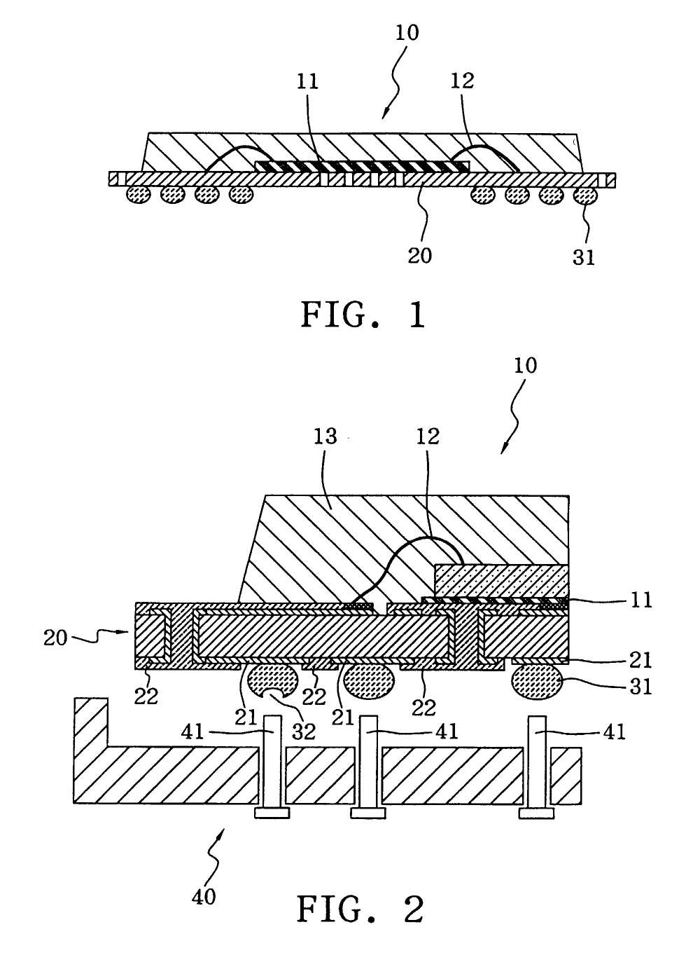

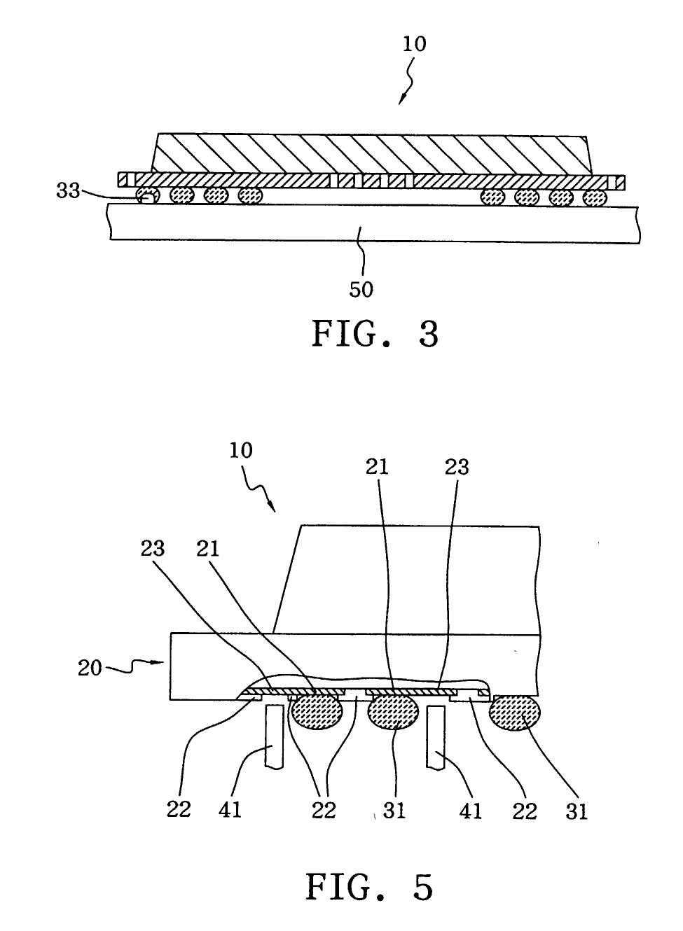

### DESCRIPTION OF PREFERRED EMBODIMENTS

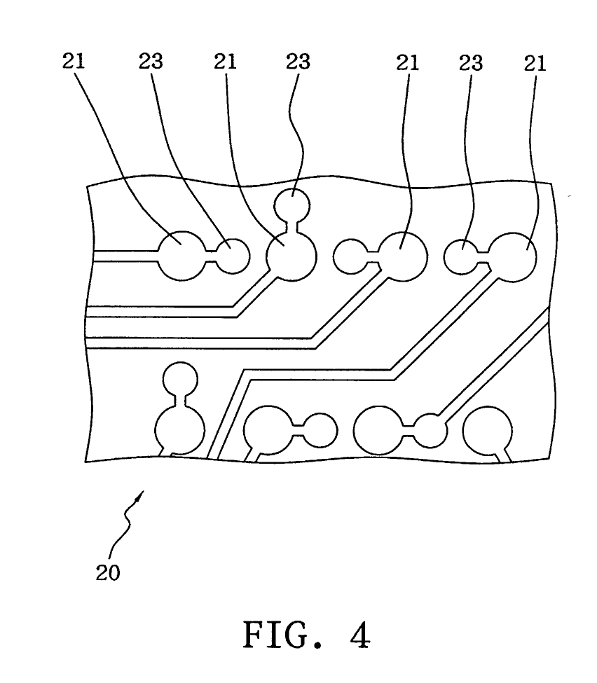

FIG. 4 illustrates a schematic diagram of a preferred embodiment according to the present invention. First, the substrate design of the present invention is different from the convention techniques, which is based on the requirements of the circuit design rules and the space to arrangement of the actual circuits. The main object is to produce the testing pads 23 on the substrate 20 and electrically connecting the testing pads 23 to the ball pads 21. For the completed substrate 20, the green paint 22 (or the anti-welding paint) for the protection (as shown in FIG. 5) cannot be overlaid on the surface of the testing pad 23, and the testing pad 23 is necessary to provide the required operational area by the probes 41 of the socket in the following test. As shown in FIG. 4, the position of the ball pad 21 according to the present invention is the same as the position of the ball pad in the conventional technique, so that it is not necessary to change the specification of the circuit board for the present invention and can be compatible with prior art technique. A horizontal extension circuit 24 is made from the position of the ball pad 21, and the other end of the circuit is connected to the testing pad 23. One surface of each of said testing pads 23 has an opening to contact an outside probe.

The substrate 20 with the testing pad is used to finish the entire process, which includes the implantation of the solder balls 31 on the ball pads 21 (as shown in FIG. 5). The completed ball grid array package 10 is placed in the testing socket 40, and the internal probes 41 are required to have corresponding positional relations with the testing pads 23. In other words, the present invention uses the probes 41 to directly contact with the testing pad 23 to complete the entire testing procedures. Therefore, it can satisfy the requirements of the testing procedure, and further keep the completeness of the shape of the solder balls 31.

The substrate 20 has at least two metal circuit layers, and the ball pads 21 and the testing pads 23 are in the same metal circuit layer of the substrate. The surface of the ball pad 21 is soldered a lead-free solder ball, and the material of the lead-free solder ball is selected from the group consisting of tin, copper, silver, zinc and their alloy thereof.

The above-described embodiments of the present invention are intended to be illustrative only. Numerous alternative embodiments may be devised by persons skilled in the art without departing from the scope of the following claims.

What is claimed is:

1. A ball grid array package comprising:
at least one chip; and
a substrate having a plurality of ball pads and a plurality of testing pads, wherein said ball pads are electrically connected to said testing pads, respectively.

2. The ball grid array package of claim 1, wherein solder balls are formed on said ball pads.

3. The ball grid array package of claim 1, wherein said substrate has at least two metal circuit layers, and said ball pads and said testing pads are in a same metal circuit layer of said substrate.

4. The ball grid array package of claim 1, wherein lead-free solder balls are formed on said ball pads.

5. The ball grid array package of claim 4, wherein the material of said lead-free solder balls is selected from the group consisting of tin, copper, silver, zinc and their alloy thereof.
